(19) United States
(12) Patent Application Publication
(10) Pub. No.: US 2025/0035551 A1
(43) Pub. Date: Jan. 30, 2025

(54) SIGNAL-TO-NOISE CORRECTION METHOD FOR ACCURATE FILMS MEASUREMENT

(71) Applicant: Applied Materials, Inc., Santa Clara, CA (US)

(72) Inventor: Khokan C. PAUL, Cupertino, CA (US)

(21) Appl. No.: 18/629,291

(22) Filed: Apr. 8, 2024

Related U.S. Application Data
(60) Provisional application No. 63/516,119, filed on Jul. 27, 2023.

(51) Int. Cl. G01N 21/55; C30B 25/16

(52) U.S. Cl. CPC G01N 21/55; C30B 25/16

(57) ABSTRACT

Embodiments of the disclosure provided herein include a system and method for improved signal-to-noise ratio correction in an epitaxial chamber integrating in-situ reflectometry. The system includes a processing chamber and a susceptor assembly configured to rotate a substrate. An in-situ reflectometry (ISR) system is coupled to the processing chamber and configured to receive ISR signals indicating properties of a substrate on the susceptor assembly. A controller is configured to determine substrate rotation speed, determine time per substrate revolution using the substrate rotation speed, determine an ISR samples acquisition per revolution using the time per substrate revolution, calculate a total samples value using an integer value and the ISR samples acquisition per revolution, determine if the total samples value is a full integer, and upon determining that the total samples value is a full integer, calibrate the ISR signals using the total samples value.

### CROSS-REFERENCE TO RELATED APPLICATIONS

This application claims priority to U.S. Patent Application No. 63/516,119, filed Jul. 27, 2023, entitled “SIGNAL-TO-NOISE CORRECTION METHOD FOR ACCURATE FILMS MEASUREMENT”, and assigned to the assignee hereof, the contents of which is hereby incorporated by reference in its entirety.

### BACKGROUND

### Field

Embodiments of the present disclosure generally relate to systems and methods of signal-to-noise ratio correction in an epitaxial chamber integrating in-situ reflectometry for real time process monitoring.

### Description of the Related Art

In-situ reflectometry is a technique employed to measure the optical properties of thin films as they are being deposited. The process involves directing a beam of light onto the film and quantifying the amount of light that is reflected back. By analyzing the reflected light, valuable information regarding the film's thickness, refractive index, and extinction coefficient can be obtained.

This method holds particular significance in semiconductor manufacturing as it enables real-time monitoring of epitaxial film growth. Epitaxy refers to the process of growing a thin film of one material on top of another material with a specific crystallographic orientation. It is a critical step in producing various semiconductor devices, including transistors and lasers.

In-situ reflectometry plays a crucial role in measuring the thickness of the epitaxial film during the deposition process. Precise control over the film's thickness is vital to achieve the desired electrical and optical properties. Furthermore, this technique can also determine the refractive index and extinction coefficient of the film, aiding in the identification of its composition and any potential structural defects.

The advantages of employing in situ reflectometry in epitaxy for semiconductor manufacturing are manifold. Firstly, it allows for real-time monitoring, enabling early detection of any issues that may arise during film growth preventing defects. Secondly, by continuously monitoring the growth process, optimal deposition conditions can be determined and implemented, resulting in higher-quality films. Lastly, the implementation of in-situ reflectometry can help reduce manufacturing costs by minimizing the occurrence of defects in the films, leading to more efficient production of semiconductor devices.

However, there can be several sources of noise during in-situ reflectometry that can have an impact on metrology and epitaxial processes controlled by in situ reflectometry. These sources of noise include instrumental noise, environmental noise, and sample noise.

Instrumental noise arises from the measurement instrument itself and can be attributed to various factors such as the electronics, the light source, and the detector. Environmental noise, on the other hand, is caused by external factors surrounding the measurement instrument, including vibrations, temperature fluctuations, and electromagnetic interference. Lastly, sample noise originates from the sample being measured and can be influenced by factors such as surface roughness, defects, and impurities.

The presence of noise can pose challenges in epitaxy measurements. It can introduce inaccuracies in measuring the optical properties of the film, affecting the determination of its thickness, refractive index, and extinction coefficient. Furthermore, noise can obscure defects within the film structure, making their identification and characterization more difficult.

Accordingly, there is a need for improved in-situ reflectometry systems for use in epitaxy that reduce noise and improve the accuracy of epitaxial film growth.

### SUMMARY

Embodiments herein are generally directed to semiconductor manufacturing and, more particularly, to systems and methods for improved signal-to-noise ratio correction in an epitaxial chamber integrating in-situ reflectometry for real time process monitoring.

In an embodiment, a substrate processing system is provided. The substrate processing system includes a processing chamber, a susceptor assembly disposed within the processing chamber and configured to rotate a substrate. An in-situ reflectometry (ISR) system is coupled to the processing chamber, the ISR system is configured to receive ISR signals indicating properties of a substrate disposed on the susceptor assembly. A controller is coupled to the processing chamber and configured to determine a substrate rotation speed, determine a time per substrate revolution using the substrate rotation speed, determine an ISR samples acquisition per revolution using the time per substrate revolution, select an integer value, calculate a total samples value using the integer value and the ISR samples acquisition per revolution, determine if the total samples value is a full integer, and upon determining that the total samples value is a full integer, calibrate the ISR signals using the total samples value.

In another embodiment, a system for in-situ reflectometry (ISR) is provided. The system includes a light source, a collimator in optical communication with the light source, a dichroic mirror disposed above an upper housing module of a processing chamber, a sensor configured to receive reflected light from the dichroic mirror. The system further includes a controller configured to receive ISR signals from the sensor indicating reflected light, determine a substrate rotation speed, determine a time per substrate revolution using the substrate rotation speed, determine an ISR samples acquisition per revolution using the time per substrate revolution, select an integer value, calculate a total samples value using the integer value and the ISR samples acquisition per revolution, determine if the total samples value is a full integer, and calibrate the ISR signals using the total samples value.

In yet another embodiment, a method for in-situ reflectometry (ISR) is provided. The method includes determining a substrate rotation speed, determining a time per substrate revolution using the substrate rotation speed, determining an ISR samples acquisition per revolution using the time per substrate revolution, selecting an integer value, calculating a total samples value using the integer value and the ISR samples acquisition per revolution, determining if the total samples value is a full integer, and calibrating ISR signals of an in situ reflectometry system using the total samples value.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other effective embodiments.

FIG. 1 is a schematic cross-sectional view of a system with an in-situ reflectometry system for processing substrates, according to certain embodiments.

FIG. 2A is a partial schematic cross-sectional view of an in-situ reflectometry (ISR) system of FIG. 1, according to certain embodiments.

FIG. 2B is a partial schematic cross-sectional view of the ISR system of FIG. 1, according to certain embodiments.

FIG. 3 illustrates a schematic block diagram view of a method of improving the signal-to-noise ratio for in-situ reflectometry, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed to semiconductor manufacturing and, more particularly, to systems and methods for improved signal-to-noise ratio correction in an epitaxial chamber integrating in-situ reflectometry for real time process monitoring.

In-situ reflectometry measures the optical properties of thin films during their deposition. By shining light onto the film and analyzing the reflected light, information about the film's thickness, refractive index, and extinction coefficient can be obtained. This real-time monitoring of epitaxial film growth allows for optimization of deposition conditions and improved film quality.

However, there are challenges associated with in-situ reflectometry, particularly the presence of noise. Sources of noise include instrumental noise from the measurement instrument itself, environmental noise from the surrounding environment, and sample noise from sample irregularity and/or caused by the film itself, especially on patterned samples, where reflected signals may vary with sample rotation. This noise can introduce inaccuracies in measuring film properties and mask defects within the film structure.

The present disclosure provides a system and method for improved signal-to-noise ratio in in-situ reflectometry (ISR). In particular, the present disclosure provides a processing system with an ISR system. The ISR system is configured to, via a controller, determine a substrate rotation speed, and then determine a time per substrate revolution using the substrate rotation speed. An ISR sample acquisition per revolution is then calculated using the time per substrate revolution and an ISR sample acquisition rate. Using an integer value, the ISR sample acquisition per substrate revolution is used to calculate a total samples value. The total samples value is then used to average or modify the incoming ISR signal into the controller. This modification improves the signal-to-noise ratio of the ISR signal, providing improved accuracy and precision in epitaxial growth, particularly in patterned substrates.

One feature of this present disclosure is to account for periodicity based on lift rotation. Periodicity is the total number of samples for an ISR period after which the sensor will repeat seeing the same position. Periodicity thus depends on the rotation speed of substrate. A received ISR signal will be calibrated, but the calibrated signal will be incorrect if the periodicity is incorrect. Based on the periodicity, a total number of signals will be averaged and be placed in the last position of ISR period, T, for all fibers, including the reference fiber, and will continue repeating the method until the end of data collection or deposition process. This averaging will smooth out the signal, reducing noise, and maintaining signal change data during the deposition process intact. Additionally, the signal-to-noise ratio improves substantially which improves ISR metrology accuracy and precision.

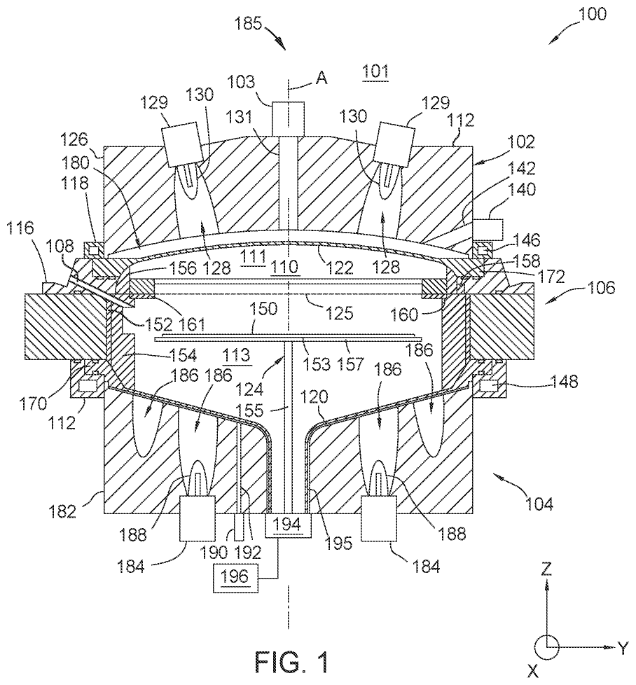

FIG. 1 is a schematic cross-sectional view of a system 101 for processing substrates, according to one implementation. The system 101 includes a process chamber 100. The process chamber 100 may be an epitaxial deposition chamber and may be used as part of a cluster tool. The process chamber 100 is utilized to grow an epitaxial film on a substrate, such as a substrate 150. The process chamber 100 creates a cross-flow of precursors (e.g., process gases) across the top surface of the substrate 150 during processing. The system 101 uses the process chamber 100 configured to conduct an epitaxial deposition operation on the substrate 150. Alternatively, the process chamber 100 may be a chemical vapor deposition (CVD) chamber, an atomic layer deposition (ALD) chamber, a physical vapor deposition (PVD) chamber, an etch chamber, an ion implantation chamber, an oxidation chamber, or other processing chamber.

The process chamber 100 includes an upper housing module 102, a lower housing module 104, a chamber body assembly 106, a susceptor assembly 124, a lower window 120, and an upper window 122. The upper housing module 102 can also be a lid or part of a process chamber lid. The susceptor assembly 124 is disposed between the upper housing module 102 and the lower housing module 104. The lower window 120 is disposed between the susceptor assembly 124 and the lower housing module 104. The upper window 122 is disposed between the susceptor assembly 124 and the upper housing module 102.

The upper housing module 102 is disposed over the susceptor assembly 124 and configured to heat a substrate, such as the substrate 150, disposed on the susceptor assembly 124. The upper housing module 102 includes an upper module body 126 and a plurality of lamp apertures 128 disposed through the upper module body 126. Each of the plurality of lamp apertures 128 includes an upper lamp 130 disposed therein. Each of the upper lamps 130 are coupled to a lamp base 129. Each of the lamp bases 129 supports one of the upper lamps 130 and electrically couples each of the upper lamps 130 to a power source (not shown). Each of the lamps 129 are secured in a generally vertical orientation within the apertures 128.

The upper housing module 102 includes a pyrometer passage 131. The pyrometer passage 131, also referred to as a light pipe, extends through the upper module body 126 from a first (e.g., lower) surface of the upper module body 126 to a second (e.g., upper) surface of the upper module body 126. The pyrometer passage 131 is configured to allow light, to travel between the surface of the substrate 150 and an in-situ reflectometry (ISR) system 185.

An upper plenum 180 is defined between the bottom surface of the upper module body 126 and the upper window 122. Heated gas is supplied to the upper plenum 180. A heated gas exhaust passage 142 is also disposed through the upper module body 126. The heated gas exhaust passage 142 is coupled to a heated exhaust pump 140. The heated exhaust pump 140 removes gas from the upper plenum 180.

The lower housing module 104 is disposed below the susceptor assembly 124 and configured to heat a bottom side of the substrate 150 disposed on the susceptor assembly 124. The lower housing module 104 includes a lower module body 182 and a plurality of lamp apertures 186 disposed through the lower module body 182. Each of the plurality of lamp apertures 186 includes a lower lamp 188 disposed therein. Each of the lower lamps 188 are disposed in a generally vertical orientation and coupled to a lamp base 184. Each of the lamp bases 184 supports one of the lower lamps 188 and electrically couples each of the lower lamps 188 to a power source.

During the substrate processing operation, the upper lamps 130 are powered to generate radiant energy (e.g. heat) and direct the radiant energy toward the substrate 150 and a susceptor 157 of the susceptor assembly 124. During the substrate processing operation, the lower lamps 188 are powered to generate radiant energy upwardly toward the substrate 150 and the susceptor 157.

The lower lamp module 104 includes a susceptor shaft passage 195 and a pyrometer passage 192. A support shaft 155 of the susceptor assembly 124 is disposed through the susceptor shaft passage 195. The susceptor shaft passage 195 is disposed centrally through the lower module body 182. The susceptor shaft passage 195 allows the support shaft 155 of the susceptor assembly 124 and a portion of the lower window 120 to pass through the lower module body 182.

A pyrometer passage 192 is disposed through the lower module body 182 outward of the susceptor shaft passage 195 to enable a lower pyrometer 190, such as a scanning pyrometer, to measure the temperature of the bottom surface of the substrate 150 or a bottom surface of the susceptor 157 of the susceptor assembly 124. The lower pyrometer 190 is disposed below the lower module body 182 adjacent to the pyrometer passage 192. The pyrometer passage 192 extends from the bottom surface of the lower module body 182 to the top surface of the lower module body 182.

An upper chamber volume 111 is the portion of a process volume 110 in which the substrate 150 is processed and one or more process gases are injected. A lower chamber volume 113 is the portion of the process volume 110 in which the substrate 150 is loaded onto (or removed from) the susceptor assembly 124. The upper chamber volume 111 may also be understood as the volume above the susceptor 157 while the susceptor assembly 124 is in a processing position. The susceptor assembly 124 is shown in a lower position (e.g., a loading position for the substrate 150) in FIG. 1. The lower chamber volume 113 is understood to be the volume below the susceptor 157 of the susceptor assembly 124 while the susceptor assembly 124 is in the processing position. The processing position is the position wherein the substrate 150 is disposed even with or above the horizontal plane 125.

An upper cooling ring 118 and a lower cooling ring 112 are disposed on opposite sides of the chamber body assembly 106. The upper cooling ring 118 is disposed on top of the inject ring 116 and is configured to cool thane inject ring 116. The lower cooling ring 112 is disposed below the inject ring 116. The upper cooling ring 118 includes a coolant passage 146 disposed therethrough. The coolant which is circulated through the coolant passage 146 may include water, oil, or another fluid. The lower cooling ring 112 includes a coolant passage 148 disposed therethrough. The coolant which is circulated through the coolant passage 148 is similar to the coolant circulated through the coolant passage 146 of the upper cooling ring 118. The upper cooling ring 118 and the lower cooling ring 112 can assist in securing the inject ring 116 in position. The upper cooling ring 118 may partially support the upper lamp module 102 while the lower cooling ring 112 may partially support the lower lamp module 104.

The use of the upper cooling ring 118 and the lower cooling ring 112 can reduce the temperature of the inject ring 116 without the need for additional cooling channels being disposed through the inject ring 116. Using the upper cooling ring 118 and the lower cooling ring 112 reduces the cost of the production of the inject ring 116, which can be more frequently replaced than the upper cooling ring 118 and the lower cooling ring 112. The present disclosure contemplates that the inject ring 116 can include one or more additional cooling passages formed therein.

One or more gas injectors 108 are disposed through one or more openings within the inject ring 116 to provide gases, such as process gases, to the process volume 110. The present disclosure contemplates that a plurality of gas injectors can be disposed through the inject ring 116 The gas injector may be positioned at an angle of greater than about 5° from an X-Y plane of the substrate 150, such as greater than about 10° from the X-Y plane. Each of the injectors are fluidly coupled to one or more process gas supply sources, such as the first process gas supply source or the second process gas supply source. For example, only a first process gas supply source is utilized. If both the first process gas supply source and the second process gas supply source are utilized, there can be two gas outlets within each gas injector. Alternatively, the first process gas supply source is a process gas while the second process gas supply source is a cleaning gas. The cleaning gas can be used to clean features of the ISR system 185 in the process volume 110 or features of the reflectometer system in the process volume 110.

The upper window 122 is disposed between the inject ring 116 and the upper housing module 102. The upper window 122 is an optically transparent window, such that radiant energy produced by the upper lamp module 102 may pass therethrough. The upper window 122 is formed of a quartz or a glass material. The upper window 122 is a dome shape and can be referred to as an upper dome, although a planar window is also contemplated. The outer edges of the upper window 122 form one or more peripheral supports 172. The peripheral support 172 is thicker than the central portion of the upper window 122. The peripheral support 172 is disposed on top of the inject ring 116. The peripheral support 172 connects to the central portion of the upper window 122. The peripheral support 172 is optically opaque, and can be formed of opaque quartz.

The lower window 120 is disposed between the susceptor assembly 124 and the lower lamp module 104. The lower window 120 is an optically transparent window, such that radiant energy produced by the lower lamp module 104 may pass therethrough. The lower window 120 is formed of a quartz or a glass material. The lower window 120 can be a dome shape and can be referred to as a lower dome, however a planar lower window 120 is also contemplated. Outer edges of the lower window 120 form a peripheral support 170. The peripheral support 170 is thicker than a central portion of the lower window 120 and 170 connects to the central portion of the lower window 120.

A variety of liners and heaters are disposed inside of the chamber body assembly 106 and within the process volume 110. As shown in FIG. 1, there is an upper liner 156 and a lower liner 154 disposed within the chamber body assembly 106. The upper liner 156 is disposed above the lower liner 154 and inward of the inject ring 116. The upper liner 156 and the lower liner 154 are configured to be coupled together or the upper liner 156 is supported on the lower line 154. The upper liner 156 and the lower liner 154 are configured to shield the inner surfaces of the inject ring 116 from the process gases within the process volume 110. The upper liner 156 and the lower liner 154 further serve to reduce heat loss from the process volume 110 to the inject ring 116. Reduced heat loss improves heating uniformity of the substrate 150 and enables more uniform deposition on the substrate 150 during processing operations (e.g., the epitaxial deposition operations). A preheat ring (PHR) 161 is supported on a ledge 160 of the lower liner 154.

An upper heater 158 and a lower heater 152 are also disposed within the chamber body assembly 106 and the process volume 110. As shown in FIG. 1, the upper heater 158 is disposed between the upper liner 156 and the inject ring 116 while the lower heater 152 is disposed between the lower liner 154 and the inject ring 116. Both of the upper heater 158 and the lower heater 152 are disposed inward of the chamber body assembly 106 to enable more uniform heating of the substrate 150 while the substrate 150 is within the process chamber 100. The upper heater 158 and the lower heater 152 reduce heat loss to the walls of the chamber body assembly 106 and create a more uniform temperature distribution around the process volume 110. Both the upper heater 158 and the lower heater 152 may be configured to have a heated fluid run therethrough or may be resistive heaters. The upper heater 158 and the lower heater 152 are further shaped to accommodate openings through the inject ring 116, such as a substrate loading port. Additionally or alternatively, the process chamber 100 may be heated using the upper lamps 130, the lower lamps 188, or a combination of both for heating. The lamps may be disposed in a vertical orientation as shown or a horizontal orientation.

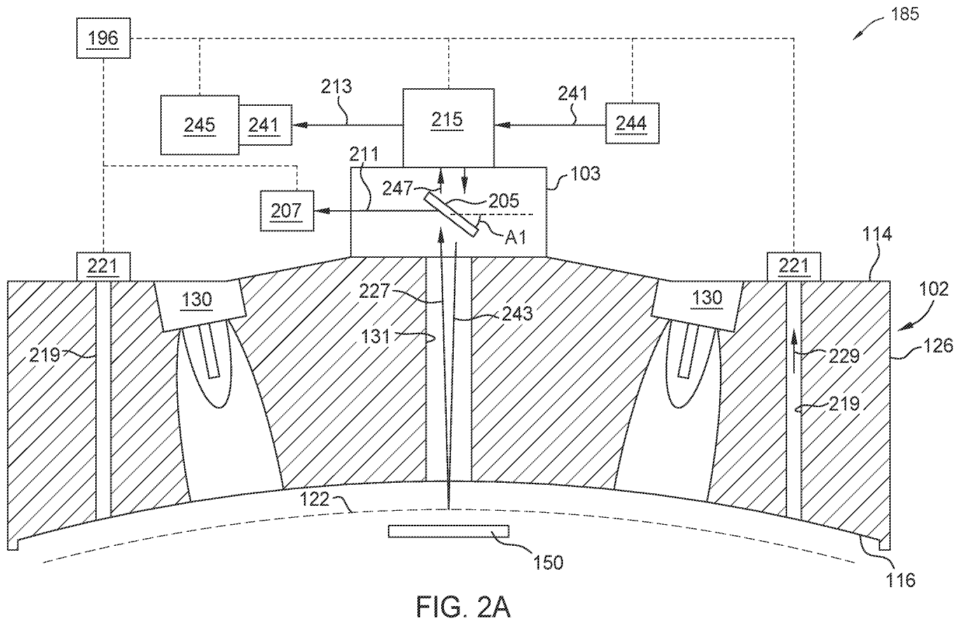

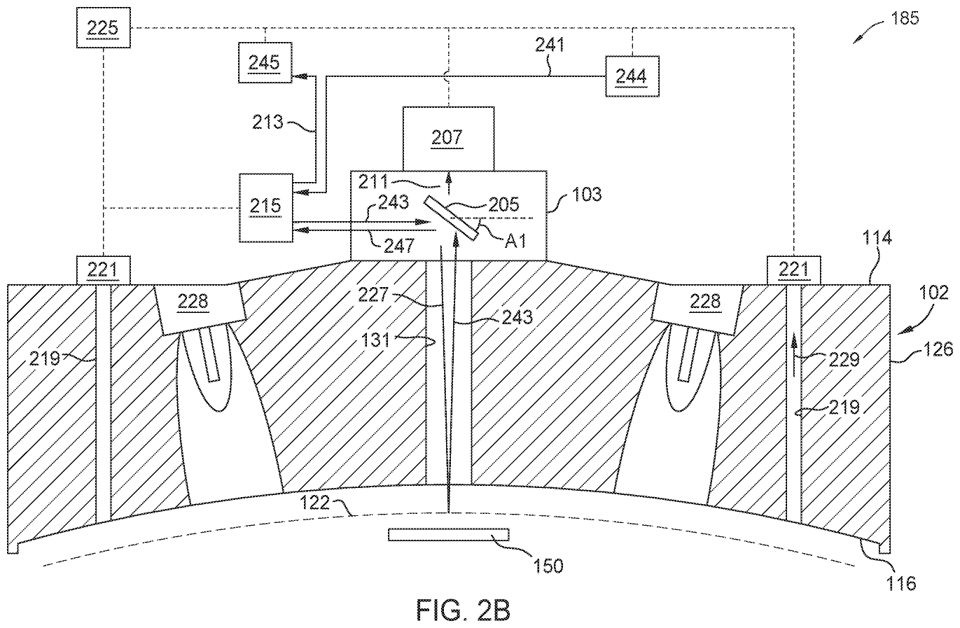

The susceptor assembly 124 is disposed within the process volume 110 and is configured to support the substrate 150 during processing. A movement assembly 194 is configured to rotate the susceptor assembly 124 and the substrate 150 during the substrate processing operation. The susceptor assembly 124 includes a planar substrate support surface 153 for supporting the substrate 150 and the shaft 155 which extends through a portion of the lower window 120 and the lower lamp module 104. The susceptor assembly 124 is coupled to the movement assembly 194 and includes for example, one or more motors or other actuators. The movement assembly 194 is coupled to a controller 196 for inducing rotation (step or continuous) about axis A, vertical actuation, angular tilt, or other movement. The controller 196 may indicate the presence of the susceptor assembly 124 to the spectrometer, may cause the light source 244 (FIG. 2A, 2B) to flash, and may store data in a memory (not shown).

FIG. 2A is a partial schematic cross-sectional view of the ISR system 185 of the system 101 shown in FIG. 1, according to one implementation. The ISR system 185 further includes a light source 244, a collimator 215, a sensor 245, a pyrometer 207, one or more preheat ring sensors 221 (two are shown), and a dichroic mirror 205 coupled to or disposed above the upper housing module 102. The ISR system 185 facilitates measurement of one or more properties of the substrate 150 (or a thin film disposed thereon). Example properties include temperature, thin film growth rate, or thickness of a thin film.

The light source 244 is configured to generate light 241. For example, the light source 244 could be a flash lamp, capable of producing full spectrum or partial spectrum light. In one example, the spectrum of light generated has a wavelength between about 200 nm to about 4 micrometers, such as 200 nm to about 800 nm or 3 micrometers to 4 micrometers. Full spectrum light allows for a wide range of light signals for analysis, however, a light source may be limited to a specific wave length of light or specific range of light wave lengths to accomplish the analysis. The light source 244 may be controlled by the controller 196. The light source 244 is in optical communication with the collimator 215, and directs light 241 to the collimator 215 upon instruction of the controller 196. Optical communication includes connected by a fiber optic cable, but other modes of light transmission are contemplated. The travel path of the light from the light source 244 may be referred to as a propagation path. The collimated light 243 leaves the collimator 215, and travels through a light pipe 131. The light pipe 131 can be a made of any material capable of transmitting light, for example, sapphire. The light pipe 131 directs the collimated light 243 to the surface of the substrate 150 (or a thin film thereon) to facilitate measurement of one or more properties of the substrate 150 (or a thin film thereon). In addition to, or as an alternative to, measurement of a substrate 150, it is contemplated that the susceptor surface (or other surface) could be measured. For example, the susceptor surface could be measured to establish an initial data set for a wobble calibration. As used herein, thin film and substrate may be used interchangeably, unless the description explicitly excludes one or the other.

The collimated light 243 is reflected off the target measurement surface, such as the substrate 150, and is reflected back as reflected light 227. The reflected light 227 travels back through the light pipe 131. The reflected light 227 leaves the light pipe 131 and travels to the dichroic mirror 205 aligned with the light pipe 131 along the travel path of the reflected light 227. The dichroic mirror 205 may be a transparent material with a dielectric coating. The dielectric coating may include, but is not limited to, magnesium fluoride, tantalum pentoxide, and titanium dioxide. The dichroic mirror 205 reflects certain wavelengths of light away, but allows other specifically selected wavelengths to pass through. A wavelength range directed to the sensor 245 may be between about, 100 nm and about 1000 nm, such as within a range of 200 nm and 800 nm, such as within a range of 200 nm and 400 nm, and such as within a range of 400 nm and 800 nm. The dichroic mirror 205 enables multiple light based sensors to be utilized by directing light of a first desired range to one sensor with the remaining light wavelengths being sent to at least another sensor. Thus, the ISR system 185 provides a compact measurement system, allowing more sensors to be included in a smaller footprint. The dichroic mirror 205 is arranged, or oriented, at an angle of incidence A1 between about, 30° and about 60°, such as within a range of 35° and 55°, with a plane near orthogonal to a longitudinal axis of the light pipe 131. However, other angles of incidence are contemplated.

As shown in FIG. 2A, light reflected from the dichroic mirror 205 is transmitted to the pyrometer 207 along light path 211. Only light wavelengths between about 1.0 μm and about 6.0 μm, such as between about 3.0 μm and about 4.0 μm, travel along light path 211 to the pyrometer 207. As noted above, properties of the dichroic mirror 205 are selected to transmit or reflect light in specified wavelength ranges. Light allowed to pass through the dichroic mirror 205, along path 247, is collimated by the collimator 215. The collimated light 213 is directed to the sensor 245. For example, the sensor 245 can be an optical spectrometer, a spectrograph configured to measure wavelength-resolved intensity. The sensor 245 can additionally include a grating, an optical lens, a filter, a charged coupled device (CCD) spectrometer array, or a linear-array photodiode detector. The filter 421 can be a short pass filter to limit the noise from a lamp 128, or a dielectric filter. A dielectric filter includes any thin film based filters that can prevent specific wavelength of light from passing therethrough. While the filter 421 is described as part of the sensor 245, it is contemplated that the filter can be located in other locations. For example, the filter 421 can be part of the dichroic mirror 205. The filter 421 is configured to allow light only of a specified wavelength to pass therethrough. In one example, the filter 421 only allows light of wavelengths below 550 nm to pass therethrough to mitigate light signal noise from lamps of the process chamber, thus improving measurement accuracy. It is contemplated that the filter 421 can be placed in any light path that includes the light reflected off the substrate 150 (e.g., reflected light 227, to the sensor 245) (e.g., reflected light 247 from dichroic mirror 205) (e.g., collimated light 243). In one example, the filter 421 is an integral component of the sensor 245, but in other examples, the filter 421 is a standalone component from the sensor 245. The filter 421 may not be included in the path, reducing the cost, complexity, and footprint of ISR system 185.

The pyrometer 207, the one or more PHR sensors 221, and the sensor 245 may be connected to the controller 196 to facilitate control or operation thereof. The controller 196 can store information, data, algorithms, or other control parameters for causing the performance of actions described herein. The controller 196 includes a central processing unit (CPU), a memory containing instructions, and support circuits for the CPU. The controller 196 controls various items directly, or via other computers or controllers. The controller 196 may be communicatively coupled to dedicated controllers, and the controller 196 functions as a central controller.

The controller 196 includes a computer processor (e.g., CPU) that is used for controlling various substrate processing chambers and equipment, and sub-processors thereon or therein. The memory, or non-transitory computer readable medium, is one or more of random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 196 are coupled to the CPU for supporting the CPU. The support circuits include cache, power supplies, clock circuits, input/output circuitry and subsystems, and the like. Operational parameters and operations are stored in the memory as a software routine that is executed or invoked to turn the controller 196 into a specific purpose controller to control the operations of the system 101 described herein. The controller 196 is configured to conduct any of the operations described herein. When executed, the instructions stored on the memory cause one or more of operations described herein to be conducted.

The upper housing module 102 may also include at least the preheat ring (PHR) sensor 221 and a PHR sensor passage 219. The PHR sensor passage 219 extends through the upper module body 126 from the first surface of the upper module body 114 to the second surface of the upper module body 126. The PHR sensor passage 219 is configured to allow light 219, to travel between the surface of the substrate 150 and the ISR system 185. The ISR system 185 includes a housing 103 that houses one or more optical elements therein to facilitate processing of optical signals.

The ISR system 185 may optionally include one or more PHR sensors 221, positioned to receive data indicating properties of a preheat ring of the system 101. Each PHR sensor 221 is configured to be in line (e.g., vertically or optically aligned) with a PHR sensor passage 219. The PHR sensor 221 is a spectrometer or a pyrometer configured to measure a property of a preheat ring (PHR), such as PHR 161 (shown in FIG. 1). In one example, each PHR sensor 221 is configured to read a reference material within or on the PHR 161 for use as a film thickness reference. For example, the reference material can be a crystalline coupon of known properties. Each PHR sensor passage 219 extends between the bottom surface and the upper surface of the upper module body 126. In such an example, the PHR sensor passage is vertically aligned with (or directed at) PHR 161 (shown in FIG. 1). The PHR sensor passage 219 may be sealed at upper and lower ends thereof by a material capable of transmitting light 219, such as quartz or sapphire. Alternatively, each PHR sensor passage 219 includes a fiber optic cable disposed thereon.

In addition, the preheat ring sensors 221 allow for an estimation of film thickness at a perimeter or edge of the substrate 150, due to the proximity of the periphery of the substrate 150 to the preheat ring 161. Thus, as deposition occurs on the preheat ring 161 during processing, the preheat ring sensors 221 can determine the thickness of film on the preheat ring sensors. This thickness is an estimate of deposited film thickness at the substrate 150 edge. Thus, using measurements through the pyrometer passage 131, a film thickness at a center of the substrate 150 can be determined, while using the measurements from the ring sensors 221, a film thickness at an edge of the substrate 150 can be determined. Therefore, center-to-edge uniformity of deposited films can be determined, and if necessary, corrected, in situ. It is contemplated that center-to-edge uniformity can be corrected by changing one or more processing parameters during the deposition process.

During processing, light from the light source 244 is used to determine film thickness or film thickness deposition rate. The light is directed from the light source 244, for example by a fiber optic cable, to the collimator 215. The collimator 215 directs the light toward a surface to be measured (e.g., the substrate 150). The light is reflected off that surface, as a reflected light. The reflected light from the measured surface 150 facilitates measurement of film thickness (or film thickness growth rate) as well as temperature. The reflected signal travels back to the dichroic mirror and is split into multiple paths (e.g., propagation sub-paths). A first propagation sub-path directs reflected light to the pyrometer 207, while a second propagation sub-path directs reflected light to the collimator 215 and then to the sensor 245. The light intensity collected by the sensor 245 is analyzed for true reflectance, which is compared with film-models, for example (Fresnel equations) using nonlinear fitting equations or other empirically derived equations to determine film thickness.

In one example, film thickness models are empirically derived by obtaining absorption/reflectance data for light at predetermined wavelengths for various films at multiple film thicknesses. The data may be collected at process conditions which approximate those of a predetermined process recipe for processing future substrates, such as a process recipe at which the model will be utilized. The data is then fit to an equation, such as a non-linear equation. Light received by the sensor 245 is analyzed for intensity (e.g., true reflectance of light reflected from the measured specimen) and fit to the empirically derived equation to determine film thickness. Stated otherwise, the amount of light reflected from the substrate 150 surface changes as a function of the thickness of a film on the substrate 150 surface. This data or equations may also take into account other optical properties, such as refractive index and extinction coefficient, of films to improve measurement accuracy.

FIG. 2B is a partial schematic cross-sectional view of the system shown in FIG. 1, according to another implementation. The ISR system 185 of FIG. 2B is configured similarly to the ISR system 185 of FIG. 2A, however, the pyrometer 207 receives the light 211 that passes through the dichroic mirror 205 and the collimator 215 receives the light 247 reflected from the dichroic mirror 205. The collimator 215 can then collimate the light 247 from the dichroic mirror 205. The sensor 245 can then receive the collimated light 213. In one embodiment, the collimator 215 may receive and collimate the reflected light 227 from the substrate prior to the dichroic mirror 205. In such an embodiment, the dichroic mirror 205 receives collimated light. In the illustrated embodiment the pyrometer 207 is located above the mirror housing 103, and the reflected light 227 and has a shorter path to the pyrometer 207.

In the ISR system 185, the measured light intensity of the light 213 is used to determine a film thickness or a growth rate of the film deposited on the surface 150. For example, a lower light intensity may indicate a greater film thickness as more light is absorbed, and a higher light intensity may indicate a lesser film thickness as more light is reflected, or vice versa depending on the composition and optical properties of the particular material being measured.

A thickness of the deposited film on the surface 150 affects the light intensity of the light 213 received by the sensor 245, such that a change in the light intensity can signal a change in the thickness of the deposited film on the surface 150. In one or more examples, a measurement spectra of the return light 213 may be filtered to provide values indicating measured light intensity only within a selected wavelength range. Such an embodiment is beneficial because radiation from lamps, such as upper lamps 130, is filtered out to improve measurement accuracy at the sensor 245. The optical filter 421 may be used to block a portion of the return light 227 which includes light with a wavelength outside a selected wavelength range. This may occur, for example, when light from the upper lamps 130 is directed into the pyrometer passage 131, such as by reflecting off of one or more internal chamber surfaces. The inadvertent light may otherwise affect measurements results at the sensor 245, and therefore, filtering the unintended wavelengths improves measurement accuracy. In one or more examples, the selected wavelength range may exclude infrared light in order to reduce the effect of background infrared lamp radiation. The wavelength range generated by the light source 244 may be light at a wavelength within a range of about 200 nm to about 780 nm, such as about 200 nm to about 500 nm, or 200 nm to about 400 nm, or about 500 nm to about 700 nm. The upper lamps 130 (or other lamps within the chamber) may be infrared lamps. In such an example, the filter 421 restricts passage of light in the infrared wavelength range (IR-A, IR-B, or IR-C), such as light having a wavelength of 780 nm to 1.3 micrometers. Therefore, the sensor 245 receives only light generated from the light source 244, improving measurement accuracy of light reflected from a surface of the substrate 150. In another example, the filter 421 filters light of 500 nm or greater, such as 550 nm or greater, as signal degradation at high temperature, e.g., 200 degrees C. and above, such as 600 degrees C. and above, begins to occur within a range of 500 nm to 550 nm, and degradation occurs at wavelengths above 550 nm. The present disclosure reduces interference from infrared lamp radiation which increases a signal-to-noise ratio of the light sensor 245 for more accurate film growth measurements.

The sensor 245 is used to monitor film growth rate in situ in the processing chamber 100 and in real-time during substrate processing. In-situ monitoring improves throughput compared to conventional approaches, since substrates need not be removed from the process chamber for thickness measurements to occur. In one example, which can be combined with other examples, the light intensity of the return light 213 is monitored continuously throughout substrate processing, or on predetermined intervals throughout substrate processing. Once a desired film thickness is achieved, the deposition process is stopped. The substrate 150 may then be removed from the process chamber 100, or further processing may occur within the process chamber 100 according to a process recipe.

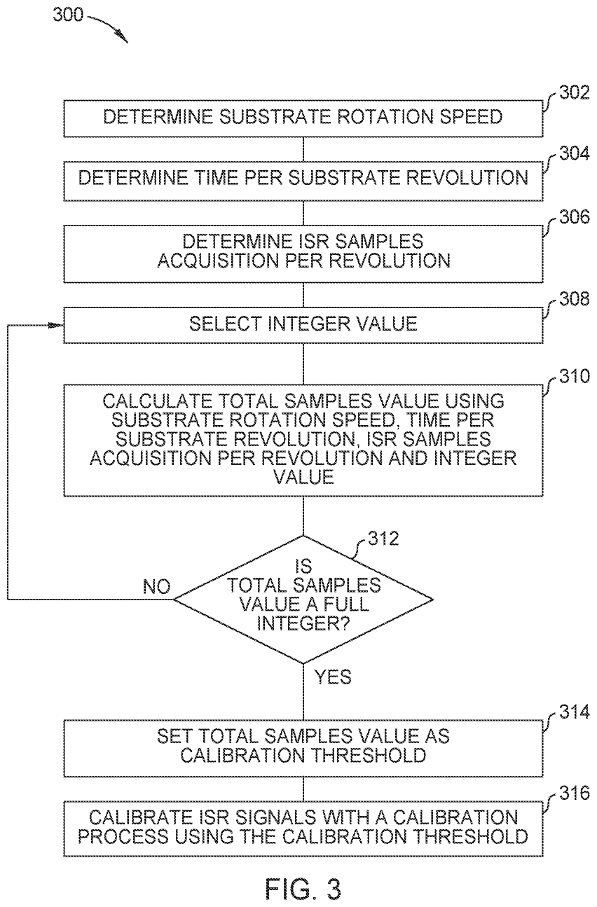

FIG. 3 illustrates a method 300 of signal-to-noise ratio correction for use in the ISR system 185 which may be executed by the controller 196. At operation 302 of method 300, a substrate rotation speed is determined for the ISR system 185. For example, the substrate rotation speed may be determined by retrieving the susceptor assembly rotation speed for the process from the controller 196. Additionally, the substrate rotation speed may be determined by retrieving the operational speed of the one or more motors of the movement assembly 194. Alternatively, the substrate rotation speed may be determined based on user input into the controller 196, e.g., via a user interface (not shown). At operation 304, the time per substrate revolution is determined, e.g., by controller 196, using the substrate rotation speed determined in operation 302. For example, the time per substrate revolution is calculated by dividing a time interval, e.g., 60 seconds, by the substrate rotation speed. The time per substrate revolution is then multiplied by an ISR sample acquisition rate at operation 306 to determine the ISR samples acquisition per revolution. The ISR sample acquisition rate may be 5 Hz, 10 Hz, 20 Hz, or more.

At operation 308, an integer value is selected. The integer value may initially be any desired integer. At operation 310, a total samples value is calculated using the ISR samples acquisition per revolution of operation 306 and the integer value of operation 308. For example, the ISR samples acquisition per revolution may be multiplied by the integer value to produce the total samples value. At operation 312, the total samples value is evaluated to determine if it is a full integer number. If it is not, the method returns to operation 308 to select a new, different integer value, then to operation 310 to recalculate the total samples value using the new integer value, before reevaluating if the recalculated total samples value is a full integer number. If the total samples value is a full integer, the total samples value is set as a calibration threshold at operation 314.

The integer value should be as small as possible while still allowing the total samples value to be a full integer. This results in the smallest possible total samples value that is an integer, which allows for improved averaging and requires a smaller amount of samples to be collected by the ISR system to calibrate the ISR signal. For example, the integer value n may be selected at operation 308 by initially setting n equal to 1, then increasing the integer value by adding 1 at each iteration of operation 308, e.g., n+1, until operation 312 is satisfied.

At operation 316, a signal calibration process begins using the calibration threshold of operation 314. In particular, the calibration process includes a signal averaging that incorporates the calibration threshold. The calibration threshold indicates which fiber index averaging begins as well as the number of points to average. For example, a substrate rotation speed of 30 rpm at an ISR samples acquisition rate of 10 Hz produces a total samples value of 20. This indicates that the collected signal, e.g., from the reflected light 227, from the collimator 215, e.g., through a plurality of fiber optic cables, will be modified from fiber index 20 with the average of 20 points, e.g., from index 1 to 20, and will continue until the process is complete. This calibration process occurs for all fiber optic cables collecting data. This modification results in reduced noise caused by rotation and other system disturbances, improving the signal-to-noise ratio and improving ISR deposition.

As shown, the present disclosure provides a system and method to improve the calibration of the received ISR signals from an ISR system during a deposition process, such as epitaxial deposition. In particular, the ISR system is configured to, via a controller, to calculate a total samples value using system characteristics, including substrate rotation speed, time per substrate revolution, ISR sample acquisition per revolution, an ISR sample acquisition rate, and an integer value. The total samples value is then used to calibrate the incoming ISR signal. This modification accounts for periodicity based on lift rotation. Based on the periodicity, a total number of signals will be averaged using the total samples value and be placed in the last position of ISR period for all fibers. This averaging results in reduced noise while maintaining the integrity of signal change data collected during the deposition process. Additionally, the improved signal-to-noise ratio improves ISR metrology accuracy and precision.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A substrate processing system, comprising:
a processing chamber;
a susceptor assembly disposed within the processing chamber and configured to rotate a substrate;
an in-situ reflectometry (ISR) system coupled to the processing chamber, the ISR system configured to receive ISR signals indicating properties of a substrate disposed on the susceptor assembly; and
a controller configured to:
calculate a total samples value;
determine if the total samples value is a full integer; and
upon determining that the total samples value is a full integer, calibrate the ISR signals using the total samples value.

2. The substrate processing system of claim 1, wherein calculating the total samples value comprises selecting an integer value and using the integer value and an ISR sample acquisition per revolution.

3. The substrate processing system of claim 2, wherein determining the ISR samples acquisition per revolution comprises using a substrate rotation speed and a time per substrate revolution.

4. The substrate processing system of claim 1, wherein determining the time per substrate revolution comprises converting the substrate rotation speed using a time interval.

5. The substrate processing system of claim 1, wherein determining the ISR samples acquisition per revolution comprises using a sample acquisition rate of the ISR system.

6. The substrate processing system of claim 1, wherein selecting an integer value comprises selecting an initial integer value and increasing the integer value from the initial integer value upon each determination that the total samples value is not a full integer.

7. The substrate processing system of claim 1, wherein calibrating the ISR signals comprises setting the total samples value as a calibration threshold, and when an amount of ISR signals exceeds the calibration threshold, averaging the ISR signals by the total samples value.

8. A system for in-situ reflectometry (ISR), comprising:
a light source;
a collimator in optical communication with the light source;
a dichroic mirror disposed above an upper housing module of a processing chamber;
a sensor configured to receive reflected light from the dichroic mirror; and
a controller configured to:
receive ISR signals from the sensor indicating reflected light;
calculate a total samples value;
determine if the total samples value is a full integer; and
calibrate the ISR signals using the total samples value.

9. The system of claim 8, wherein calculating the total samples value comprises selecting an integer value and using the integer value and an ISR sample acquisition per revolution.

10. The system of claim 9, wherein determining the ISR samples acquisition per revolution comprises using a substrate rotation speed and a time per substrate revolution.

11. The system of claim 8, wherein determining the time per substrate revolution comprises converting the substrate rotation speed using a time interval.

12. The system of claim 8, wherein determining the ISR samples acquisition per revolution comprises using a sample acquisition rate of the in-situ reflectometry system.

13. The system of claim 8, wherein selecting an integer value comprises selecting an initial integer value and increasing the integer value from the initial integer value upon each determination that the total samples value is not a full integer.

14. The system of claim 8, wherein calibrating the ISR signals comprises setting the total samples value as a calibration threshold, and when an amount of ISR signals exceeds the calibration threshold, averaging the ISR signals by the total samples value.

15. A method for in-situ reflectometry (ISR), comprising:
calculating a total samples value;
determining if the total samples value is a full integer; and
calibrating ISR signals of an in situ reflectometry system using the total samples value.

16. The method of claim 15, wherein calculating the total samples value comprises selecting an integer value and using the integer value and an ISR sample acquisition per revolution.

17. The method of claim 16, wherein determining the ISR samples acquisition per revolution comprises using a substrate rotation speed and a time per substrate revolution.

18. The method of claim 15, wherein determining the time per substrate revolution comprises converting the substrate rotation speed using a time interval.

19. The method of claim 15, wherein selecting an integer value comprises selecting an initial integer value and increasing the integer value from the initial integer value upon each determination that the total samples value is not a full integer.

20. The method of claim 15, wherein calibrating the ISR signals comprises setting the total samples value as a calibration threshold, and when an amount of ISR signals exceeds the calibration threshold, averaging the ISR signals by the total samples value.
